(19) United States
(12) Patent Application Publication
(10) Pub. No.: US 2008/0291621 A1
(43) Pub. Date: Nov. 27, 2008

(54) System and method for information handling system adaptive venting and cooling

(76) Inventors: Laurent A. Regimbal, Round Rock, TX (US); Eric Tunks, Austin, TX (US); Edmond I. Bailey, Cedar Park, TX (US)

Correspondence Address: HAMILTON & TERRILE, LLP, P.O. BOX 203518, AUSTIN, TX, 78720, US

(21) Appl. No.: 11/753,328

(22) Filed: May 24, 2007

(51) Int. Cl. H05K 7/20

(52) U.S. Cl. 361/686; 361/687

(57) ABSTRACT

An information handling system cooling system operates according to a thermal profile selected by a thermal profile manager based upon venting detected as available through a chassis wall. Venting through the chassis is provided, in part, by vent openings formed in a blank coupled to the chassis. A first thermal profile is selected if the blank is detected coupled to the chassis. A second thermal profile is selected if the blank is replaced with a component. The thermal profile is selected based upon detection of the component by the information handling system or, alternatively, by detection of the blank coupled to the chassis.

### BACKGROUND OF THE INVENTION

1. Field of the Invention

The present invention relates in general to the field of information handling system cooling, and more particularly to a system and method for information handling system adaptive venting and cooling.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems continue to grow more powerful and capable over time. Two unfortunate yet common byproducts of improved information handling system performance are increased use of power and increased thermal management difficulties. The thermal management difficulties include the removal of greater amounts of heat typically associated with more powerful components as well minimizing associated acoustics, such as fan noise. Information handling system manufacturers struggle to pack as much processing capability as possible into a housing that has a minimal footprint. As an example, information handling system servers are often assembled in a relatively small 1U chassis. A 1U chassis offers the advantage of a small footprint that fits well in the small closet-like areas typically reserved for use by server information handling systems. However, the relatively small area available within a 1U chassis generally means that the chassis ends up with a dense population of components. Often, component configurations can vary substantially because the motherboard within the chassis typically includes a variety of daughter board slots that end users can choose to populate with components or leave empty.

The ability to selectively add or delete components within an information handling system provides end users with considerable flexibility for configuring the information handling system to accomplish desired tasks. However, different configurations of components within an information handling system chassis will typically have different thermal profiles. One reason for the difference in thermal profile is that different types of components generate different amounts of thermal energy as a byproduct of their operations. For example, more powerful CPUs tend to generate greater amounts of heat. Another reason for the difference in thermal profile is that greater numbers of components tend to generate greater amounts of heat. In addition, greater numbers of components increase the impedance to airflow within the chassis. Impedance is a measure of resistance to airflow within the chassis which tends to increase with increased numbers of components since the components tend to block airflow between the cooling fan and vent openings formed in the chassis. To manage variations in thermal profile, a cooling system within an information handling system chassis operates one or more cooling fans at rates that are set at least in part by the number and type of components built into the information handling system. Generally, during the design of the information handling system, engineers will determine appropriate operating parameters for the cooling system, such as fan speed settings to be used at various internal temperatures based on the components used in the information handling system. Such settings will not remain valid if components are added to the chassis by the end user, especially if the components change the impedance within the chassis, such as by blocking venting of air from the chassis. As a result, thermal profiles are typically based on worst case venting scenarios, resulting in fan speeds that are sometimes greater than needed, thus producing greater acoustics and consuming greater amounts of energy.

### SUMMARY OF THE INVENTION

Therefore, a need has arisen for a system and method which adapts an information handling system thermal profile to variable venting configurations.

In accordance with the present invention, a system and method are provided which substantially reduce the disadvantages and problems associated with previous methods and systems for setting an information handling system thermal profile. Venting available through a chassis of the information handling system is detected and a thermal profile is selected based upon the available venting.

More specifically, an information handling system has a motherboard disposed in a chassis, the motherboard supporting communication between components of the information handling system, such as a CPU, RAM, a hard disk drive and firmware devices, like an IMC or a BIOS running on a chipset. The motherboard includes one or more component coupling points, such as slots that accept daughter cards. An opening formed in a wall of the chassis proximate a slot allows access to a component inserted in the slot from the exterior of the chassis when the slot is populated by a component, such as a PCI card or a PCI Express card. A blank fits in the chassis wall when the slot is not populated by a component. Venting formed in the blank reduces impedance of airflow through the chassis so that a cooling fan providing cooling airflow through the chassis faces reduced resistance. A thermal profile manager associated with the information handling system detects whether a component or a blank is fitted in the chassis wall opening. If a component is fitted in the chassis opening, a first thermal profile is selected to operate the cooling fan based on airflow impedance without venting through the blank. If a blank is fitted in the chassis opening, a second thermal profile is selected to operate the cooling fan based on the reduced airflow impedance provided by additional venting available through vent openings formed in the blank.

The present invention provides a number of important technical advantages. One example of an important technical advantage is that an information handling system thermal profile automatically adjusts based upon impedance of airflow within a chassis. Automatic detection of components that alter impedance within a chassis allows selection of a thermal profile that more accurately reflects operational characteristics of the information handling system. For example, thermal profiles are automatically selected based on which component sockets or cards are populated so that a chassis wall proximate such sockets or cards may include venting. If a socket or card is unpopulated extra venting provided at the chassis wall reduces impedance through the chassis so that cooling fans may run at slower rates for reduced acoustics and power consumption. If the socket or card is populated, a different thermal profile is selected based on the increased impedance so that adequate cooling fan speed provides sufficient cooling.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts a cutaway view of an information handling system having component openings in a chassis wall that are selectively fitted with a component or a blank having venting; and

FIG. 2 depicts a side view of the exterior of an information handling system chassis having component openings populated by components or by blanks having venting.

### DETAILED DESCRIPTION

Information handling system venting configurations are automatically detected for selection of a thermal profile that defines cooling system operations associated with the information handling system. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

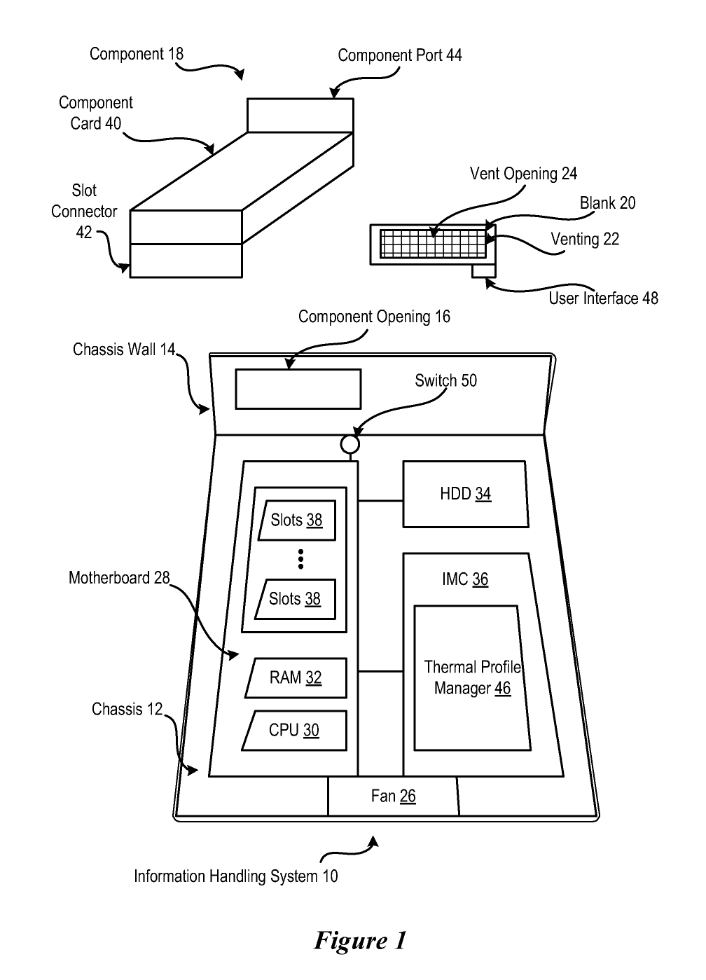

Referring now to FIG. 1, cutaway view of an information handling system 10 is depicted. A chassis 12 of information handling system 10 has component openings 16 formed in a chassis wall 14. Component openings 16 are selectively fitted with a component 18 or a blank 20 having venting 22. Venting 22 has one or more vent openings 24 that allow airflow between the exterior and interior of chassis 12, such as cooling airflow driven through chassis 12 by a cooling fan 26. Chassis 12 supports a motherboard 28 that provides communication between components of information handling system 10, such as a CPU 30, RAM 32, a hard disc drive 34 and an IMC 36. Motherboard 28 also includes coupling points, such as slots 38, which accept additional components, such as components that support communication with external devices through ports exposed at the exterior of chassis wall 14. As an example, component 18 depicted by FIG. 1 is a PCI card 40 having a slot connector 42 to couple to a slot 38 and a port 44 to couple to a cable external to chassis 12. Other examples of components may include PCI Express cards, USB cards, graphics cards, SAS cards, or other such devices that extend a port through chassis wall 14 through a component opening 18.

In operation, information handling system 10 processes information through coordinated operation of components communicating through motherboard 28. During processing, the components produce excess heat that is removed from the interior of chassis 12 by a cooling system, such as cooling fan 26 run at variable speeds by commands of a controller. For example, IMC 36 provides a thermal profile that defines the speed of rotation of fan 26 according to the temperature sensed within chassis 12. In other embodiments, other types of firmware instructions may provide a thermal profile to cooling fan 26, such as a BIOS running on a chipset. Cooling airflow provided by cooling fan 26 is drawn through and exited from venting formed in chassis wall 14. The amount of venting available through chassis wall 14 determines the impedance within chassis 12, meaning the resistance to airflow. Having greater amounts of venting reduces impedance in chassis 12 so that a given amount of airflow can be drawn with reduced rotation speeds of cooling fan 26 when compared with reduced amounts of venting having increased impedance. Thus, for example, a thermal profile manager 46 running on IMC 26 provides a first thermal profile for cooling fan 26 if a first amount of venting is present and a second thermal profile for cooling fan 26 if a second amount of venting is present. The first thermal profile operates cooling fan 26 at a first set of rotation speeds associated with a first set of temperatures based on the impedance provided by the first amount of venting. The second thermal profile operates cooling fan 26 at a second set of rotation speeds associated with a second set of temperatures based on the impedance provided by the second amount of venting.

In order to select the thermal profile for operating cooling fan 26, thermal profile manager 46 detects the venting available through chassis wall 14. In part, the venting available through chassis wall 14 depends upon whether a blank 20 with venting 22 is fitted in chassis wall opening 16 or a component 18 with a component port 44 is fitted in chassis wall opening 16. In one embodiment, thermal profile manager 46 determines if a component 18 is fitted in chassis wall opening 16 during discovery of components at boot of information handling system 10, such as during POST. If a component 18 is detected at a slot 28, thermal profile manager 46 selects a thermal profile associated with a lack of venting through the chassis opening 16 associated with the populated slot 28. If a component 18 is not detected at a slot 28, thermal profile manager 46 selects a thermal profile associated with venting available through chassis wall opening 16 associated with the slot 28. When component configurations are changed, such as when an end user adds components 18 to or removes components 18 from slots 28, thermal profile manager 46 adjusts the thermal profile used to determine the rotation speed of fan 26 based on the venting available through the openings 16 associated with the added or remove components 18. Alternatively, thermal profile manager 46 determines a thermal profile by detecting that a component blank 20 is fitted in chassis wall 14. For example, blank 20 includes an interface 48 aligned to engage a switch 50 when fitted in opening 16. Thermal profile manager 46 detects activation of switch 50 to detect blank 20 and thus selects a thermal profile associated with venting 22 provided by blank 20. In other alternative embodiments, other types of indicators may be used to determine venting available through chassis wall 14.

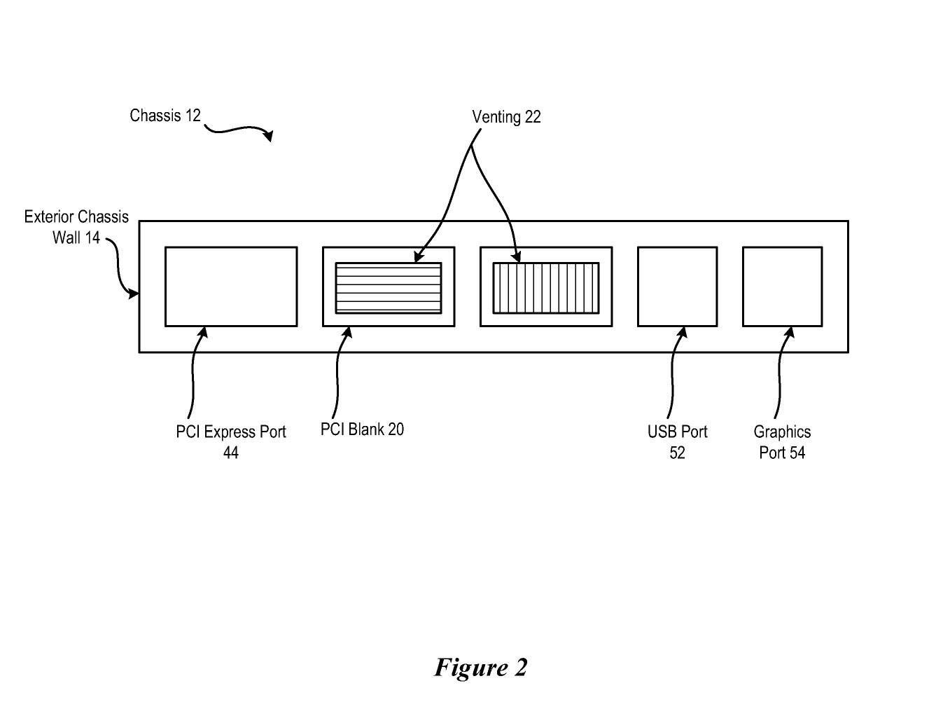

Referring now to FIG. 2, a side view depicts the exterior of an information handling system chassis 12 having component openings populated by components or by blanks having venting. The exterior of chassis wall 14 is formed to have a plurality of openings with each opening sized to fit a predetermined component. For example, as depicted by FIG. 2, one opening is populated with PCI express component port 44, another is populated with a USB component port 52, and another is populated by a graphics component port 54. A blank 20 sized to fit in a PCI component opening is fitted into a PCI opening in the place of a PCI component port. Blank 20 has venting 22 that allows communication of airflow between the interior and exterior of chassis 12. Additional venting 22 is formed in chassis wall 14 as a permanent fixture to ensure that communication of airflow between the interior and exterior of chassis 12 has a minimum area. If blank 20 is replaced with a PCI component port, venting 22 associated with blank 20 becomes unavailable. Thermal profile manager 46 adjusts the thermal profile used by the cooling system associated with chassis 12 for the reduced inductance resulting from the loss of venting 22 through blank 20. Alternatively, if ports 44, 52 or 54 are replaced with a blank having venting 22, thermal profile manager 46 adjusts the thermal profile used by the cooling system for the increased inductance provided by the additional venting. Reduced inductance means reduced fan speeds for improved power consumption and acoustic performance.

Although the present invention has been described in detail, it should be understood that various changes, substitutions and alterations can be made hereto without departing from the spirit and scope of the invention as defined by the appended claims.

What is claimed is:

1. An information handling system comprising:
a chassis having exterior walls, the walls having one or more blanks, the blanks selectively removable for replacement by a component, the blanks having venting;
a motherboard disposed in the chassis, the motherboard operable to accept plural components, the components operable to cooperate to process information;
a cooling fan disposed proximate the chassis, the cooling fan aligned to provide cooling airflow across the components at variable fan speeds, the fan speeds determined by reference to a thermal profile; and
a thermal profile manager interfaced with the cooling fan and operable to select a thermal profile for the cooling fan based on whether a blank or a component is present at the chassis wall.

2. The information handling system of claim 1 wherein the thermal profile manager is further operable to detect whether a blank or a component is present at the chassis wall by discovery of the component.

3. The information handling system of claim 1 wherein the thermal profile manager is further operable to detect whether a blank or a component is present at the chassis wall by discovery of the blank.

4. The information handling system of claim 3 wherein the blank comprises an interface that engages a switch associated with the chassis, the thermal profile manager discovering the blank by engagement of the interface and the switch.

5. The information handling system of claim 1 further comprising first and second thermal profiles, the first thermal profile associated with a first impedance having a vent formed in the blank, the second thermal profile associated with a second impedance having the blank replaced by the component.

6. The information handling system of claim 1 wherein the component that replaces the blank comprises a PCI card.

7. The information handling system of claim 1 wherein the component that replaces the blank comprises a PCI Express card.

8. The information handling system of claim 1 wherein the component comprises a graphics card.

9. The information handling system of claim 1 wherein the component comprises a USB card.

10. A method for cooling an information handling system, the method comprising:
detecting venting available at a chassis of the information handling system;
selecting a thermal profile based upon the detected venting; and
cooling the chassis according to the selected thermal profile.

11. The method of claim 10 further comprising:
detecting a change in the venting available at the chassis;
adjusting the thermal profile to adapt to the change in venting; and
cooling the chassis according to the adjusted thermal profile.

12. The method of claim 10 wherein detecting venting further comprises:
detecting a predetermined component, the predetermined component coupling to the chassis in the place of venting.

13. The method of claim 12 wherein the venting comprises a blank coupled to the chassis, the blank having vent openings.

14. The method of claim 13 wherein the predetermined component comprises a PCI card.

15. The method of claim 13 wherein the predetermined component comprises a PCI Express card.

16. The method of claim 10 wherein detecting venting available at a chassis further comprises:
engaging a switch with a blank coupled to the chassis; and
integrating a vent opening in the blank.

17. A system for cooling an information handling system, the system comprising:
a cooling system operable to provide cooling airflow through an information handling system chassis according to a thermal profile; and
a thermal profile manager interfaced with the cooling system and operable to select a thermal profile for the cooling system based on detection of venting available through a wall of the chassis.

18. The system of claim 17 wherein the venting comprises a blank associated with a component, the blank having vent openings.

19. The system of claim 18 wherein the component comprises a PCI card having a port disposed to extend through the wall of the chassis.

20. The system of claim 18 wherein the component comprises a PCI
Express card having a port disposed to extend through the wall of the chassis.
